(19) United States
(12) Patent Application Publication
(10) Pub. No.: US 2002/0063567 A1
(43) Pub. Date: May 30, 2002

(54) Measurement device with remote adjustment of electron beam stigmation by using MOSFET ohmic properties and isolation devices

(75) Inventors: Gustavo E. Aizenberg, ST. Nes Ziona (IL); Amir Len, Tel-Aviv (IL)

Correspondence Address: PATENT COUNSEL, APPLIED MATERIALS, INC., Legal Affairs Department, P.O. BOX 450A, Santa Clara, CA, 95052, US

(73) Assignee: Applied Materials, Inc.

(21) Appl. No.: 09/727,967

(22) Filed: Nov. 30, 2000

(51) Int. Cl. G01R 31/305

(52) U.S. Cl. 324/751

(57) ABSTRACT

A device and method are presented for adjusting Quadrupole Stigmation Magnetic Lenses of scanning electron microscope systems and for similar systems requiring high resolution particle beams. The ohmic characteristics of MOSFET devices are changed by electronic commands to calibrate particle beams, with the benefit that the calibration may be performed automatically and remotely. Automatic electronic particle beam adjustment provides flexibility by allowing a system to be universally available for different types of specimens under test requiring inspection under different aperture and acceleration voltages. Additionally, transistors provide a solution to applications which require low resistance remote control where devices such as programmable resistors or potentiometers are problematic.

### BACKGROIJND OF THE INVENTION

1. . Field of the Invention

The present invention relates to a measurement device that uses high resolution particle beams and, in particular, a method and apparatus for the adjustment of high resolution particle beams. More particularly, it relates to a device and method of adjusting the cross-sectional shape of a particle beam using Quadrupole Stigmation Magnetic Lenses of scanning electron microscope systems or a similar systems.

2. Description of the Related Art

The Scanning Electron Microscope (SEM) uses an electron or particle beam to image and measure features on a semiconductor wafer at a much higher resolution than images captured by an optical microscope. The electron beam is shaped and focused by magnetic and electrostatic fields or “lenses” within an electron column to provide a remarkably precise and narrow electron beam. The beam is scanned on an area of interest by deflection coils for imaging at dimensions that are much smaller than the wavelengths of visible light.

In practical instruments used today, electrostatic lenses are used only in the electron gun, while magnetic lenses are used through the rest of the SEM. Electrostatic lenses require conducting surfaces very close to the path of an electron beam in order to produce an electrical field of high intensity. Magnetic fields, on the other hand, are usually formed by coils that are located completely outside the electron gun. FIG. 9 illustrates a conventional SEM 90 having an electron gun 91, magnetic lenses 92a-92c, apertures 93a,93b, and a scanning coil 94. The electron beam 96 is shown impinging a sample 95.

A stigmator set is one of the required magnetic lens sets for an SEM, which corrects for aberrations in the electron beam, such as astigmatism. Astigmatism is produced by contamination charges and inaccuracies in the construction or alignment of apertures in the electron column and causes the cross-sectional shape of the electron beam to become elliptically deformed. Since astigmatism produces a loss of image resolution, a quadrupole field is generally applied to the elliptically-shaped electron beam in order to produce a circularly-shaped electron beam. Conventionally, the quadrupole field is formed by using two magnetic quadrupole (cylindrical) lenses.

FIG. 7 illustrates a conventional stigmator device 70 for adjusting stigmation with one quadrupole (four coils) L1-L4, wherein the stigmator is an internal assembly of the electron microscope column. The coils L1-L4 of the quadrupole are connected at a common point 12 and are typically supplied by a current source 11, I_{STIG}, and have a floating voltage-to-current amplifier configuration. The current I_{STIG} from the current source 11 is divided by potentiometers P1,P2 and then supplied to the coils L1-L4.

In an ideal quadrupole, wherein each coil has the same properties, the potentiometers P1,P2 could be adjusted to their middle point such that all currents through coils L₁, L₂, L₃ and L₄ would be equal to one half of I_{STIG}. Under this condition, it would only be necessary to select I_{STIG} for minimum astigmatism.

Due to coil imperfections, however, it is essential to balance the current through the coils in pairs I₁, I₂ and I₃, I₄ using potentiometers P₁ and P₂, respectively, wherein I₁+I₂=I₃+I₄=I_{STIG}. The potentiometer settings are specific for given aperture and acceleration voltage values of an electron column, so that any changes to the aperture and acceleration voltages require re-calibration through re-adjustment of the potentiometer settings. Since potentiometer setting requires manual adjustment, it is standard practice to perform the adjustment and calibration only once during system integration and to refrain from changing the aperture and acceleration voltages thereafter.

Coil imperfections also give rise to beam shifts that adversely affect beam alignment. The beam shifts are compensated by unbalancing the currents through the four coils of the magnetic quadrupole. Conventionally, shift adjustment is performed by adjusting the potentiometers. Again, since potentiometer setting requires manual adjustment, it is standard practice to perform the adjustment and calibration only once during system integration.

The cross-sectional shape of a particle beam is also affected by the selection of working conditions for the scanning electron microscope, such as an acceleration voltage, cap voltage, probe current, and tilt currents. In conventional systems, the calibration of stigmation balance trimmers is manually performed only once during the original setting of the working conditions. As a result, any subsequent changes to the working conditions are uncompensated.

The latest analysis of constraints for new generation systems indicate that there is a need for a more flexible, or even automatic way of adjustment; especially, if the acceleration voltages and apertures are parameters to be changed by the operator.

Although digital programmable resistors are available for automatic adjustment in place of manual potentiometers, they lack suitable specifications, such as resistance ranges and current/voltage capacities. An alternative device for automatic adjustment is a motor-potentiometer assembly, however, these devices are deficient due to their associated trembling and vibration problems.

FIG. 8 shows a conventional method for calibrating a scanning electron microscope. Working conditions are first selected, including an acceleration voltage, a cap voltage, a probe current and tilt currents. Then, aperture alignment currents are manually calibrated. Next, one of the following two steps is traditionally performed. Either the stigmation balance trimmers are manually calibrated once for an initial working condition or this calibration step is entirely skipped. Next, the stigmation currents are manually calibrated followed by the automatic focus calibration step. Since the stigmation balance trimmers are not calibrated every time the working conditions are changed, prior art scanning electron microscopes suffer from the problem of strong image drifts while calibrating the stigmation currents. This phenomenon prevents the implementation of an automatic stigmation calibration algorithm.

### SUMMARY OF THE INVENTION

The present invention overcomes the problems associated with prior art scanning electron microscopes by providing automatic calibration of stigmation balance trimmers from a remote location. An adjustment of the stigmation balance trimmers by electronic command allows the electronic beam of the scanning electron microscope to be adjusted every time an operator changes the working conditions (i.e., apertures and acceleration voltages).

In the present invention, manual adjustment of system parameters is replaced by a technique based on electronic commands. This is advantageous for new generation machines which require frequent changes to apertures and acceleration voltages by the operator in order to provide high resolution. The basic idea, as applied to a SEM, is extendable to other applications that require the control of low resistance values.

The present invention is directed to a calibration device which provides resistance-based adjustment using ohmic characteristics of a transistor, wherein the calibration device includes a constant current source, a plurality of coils which are commonly connected at one end, and a plurality of transistors, each of said transistors being connected to a corresponding second end of said coils and to said constant current source.

Other objects and features of the present invention will become apparent from the following detailed description considered in connection with the accompanying drawings which disclose embodiments of the present invention. It should be understood, however, that the drawings are designed for purposes of illustration only and not as a definition of the limits of the invention.

### BRIEF DESCRIPTION OF THE DRAWINGS

In the drawings, similar reference characters denote similar elements throughout the different views:

FIG. 1 illustrates a schematic circuit of a first embodiment of the calibration circuit of the present invention.

FIG. 2 illustrates a graph of the DC analysis of currents I₁ and I₂ vs. the control voltage (V_{GS}) for the circuit of FIG. 1 at different I_{STIG} current levels (i.e., I_{STIG}=50 mA, 100 mA, and 150 mA), wherein I₁ and I₂ are normalized to I_{STIG}.

FIG. 3 illustrates a schematic circuit of a second embodiment of the calibration circuit of the present invention.

FIG. 4 is a graph of simulated DC analysis for current I₁ vs. the control voltage (V_{GS}) for the circuit of FIG. 3 at different I_{STIG} current levels (i.e., I_{STIG}=50 mA, 100 mA, and 150 mA), wherein I₁ is normalized to I_{STIG} and includes the observed error between the 50 mA and 150 mA curves.

FIG. 5 is a graph of measured DC analysis for current I₁ vs. the control voltage (V_{GS}) circuit of FIG. 3 at different I_{STIG} current levels (i.e., I_{STIG}=50 mA, 100 mA, and 150 mA), wherein I₁ is normalized to I_{STIG} and includes the observed error between the 50 mA and 150 mA curves.

FIG. 6 illustrates a flow chart of the calibration process for the present invention.

FIG. 7 illustrates a schematic circuit for a conventional calibration circuit.

FIG. 8 illustrates a flow chart for a conventional calibration process.

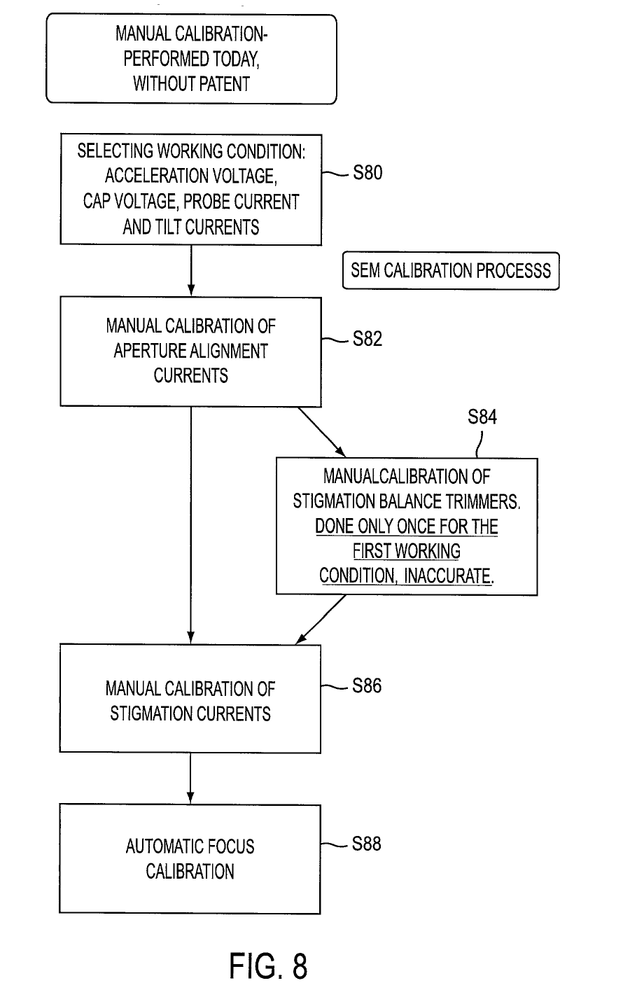

FIG. 9 illustrates a conventional scanning electron microscope.

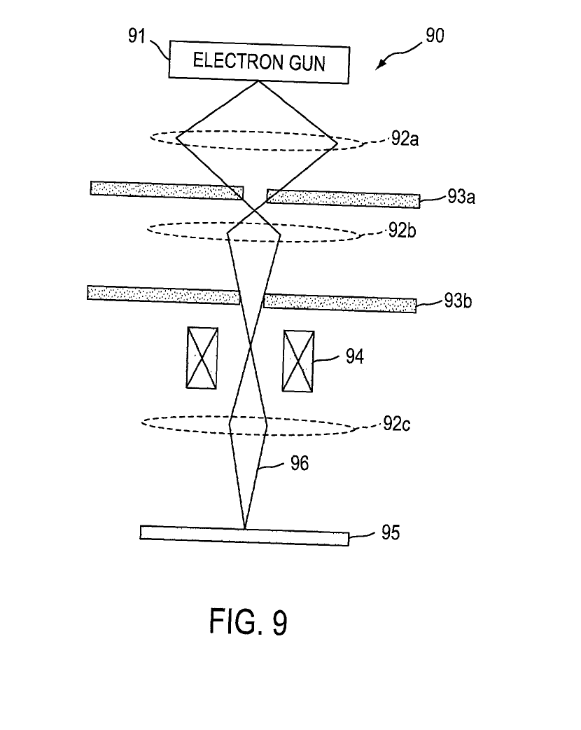

### DETAILED DESCRIPTION OF PREFERRED EMBODIMENTS

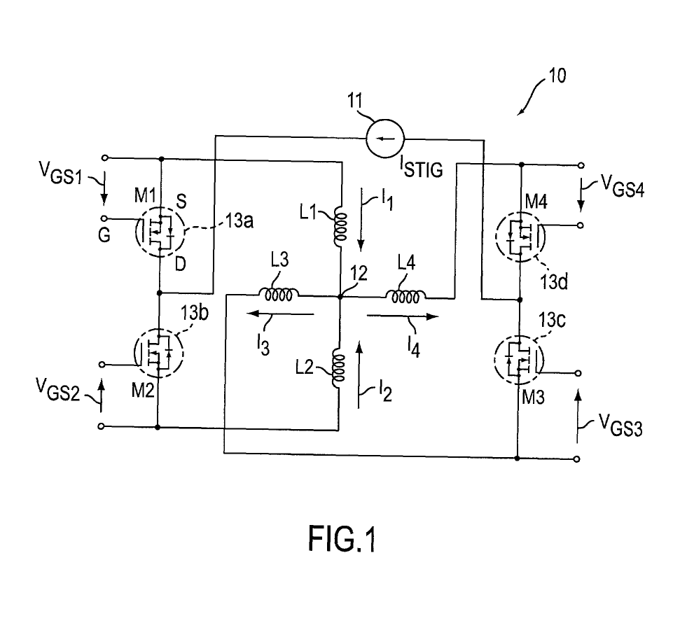

FIG. 1 illustrates a first embodiment of a stigmation adjustment circuit 10 having a quadrupole constructed from four coils L1, L2, L3, and L4, each connected at one end at a common point 12. A second end of each coil L1, L2, L3 and L4 is connected to a source terminal of a MOSFET (M1, M2, M3, and M4, respectively). A constant current source 11 is connected at one end to the drain terminals of M1 and M2 and at a second end to the drain terminals of M3 and M4, so that the circuit 10 is supplied with current I_{STIG}.

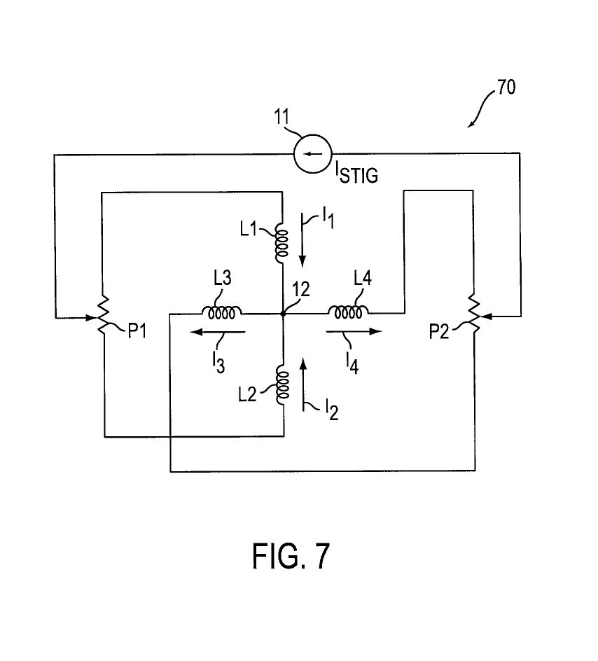

The stigmation adjustment circuit 10 takes advantage of the ohmic properties in the ohmic or triode region of the MOSFET output characteristics, which causes the MOSFET to behave as a non-linear resistor. As a result, the transistor-pairs M1, M2 and M3, M4 can replace the potentiometers P1 and P2, respectively, in the circuit of FIG. 7.

The drain current of a MOSFET can be expressed as:

I_{D}=k W[2(V_{GS}−V_{TH})V_{DS}−V²_{DS}]

2L

Where k is a constant, W is the width of the device, L is the channel length, V_{TH} is the threshold voltage, V_{GS} and V_{DS} are the gate-source and drain-source voltages, respectively. This equation is valid only under the condition that V_{DS}<V_{GS}−V_{TH}. If transistors M1, M2, M3, and M4 are identical, then the voltage applied across the source and gate terminals of each transistor are equal V_{GS1}=V_{GS2}=V_{GS3}=V_{GS4}=V_{GS}, where V_{GS} is the gate-source voltage at the quiescent point, and the currents I₁, I₂, I₃ and I₄ are equal to I_{STIG}/2.

The following description focuses on transistor pair M1, M2, however, it should be understood that transistor pair M3, M4 operate analogously and the description thereof is omitted. When V_{GS1}=V_{GS}+ΔV_{GS} and V_{GS2}=V_{GS}−ΔV_{GS}, the drain-source resistance R_{DSI} of transistor M1 decreases and the drain-source resistance R_{DS2} of M2 increases. Consequently, the current I₁ through coil L1 increases and the current I₂ through coil L2 decreases. Therefore, by adjusting the control voltage, ΔV_{GS}, it is possible to change the value of the currents I₁ and I₂ while keeping the sum of currents constant at I₁+I₂=I_{STIG}.

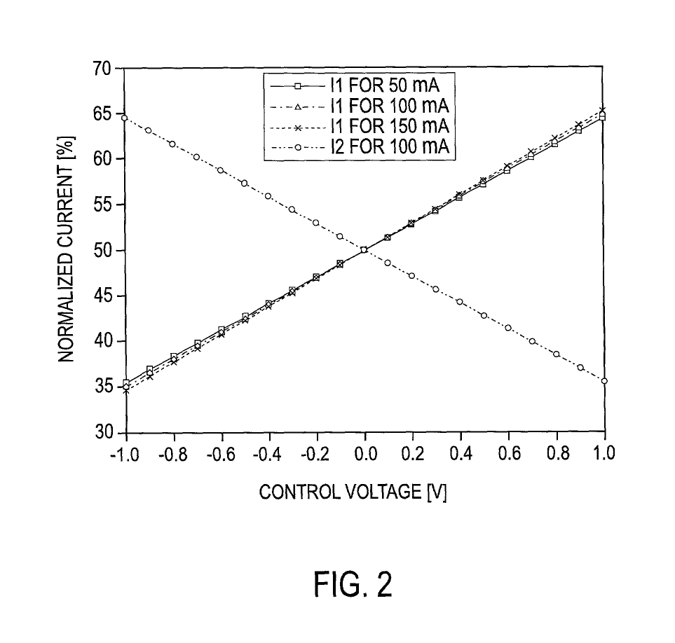

FIG. 2 shows a graph of the DC analysis for circuit 10 of FIG. 1. The graph shows I₁ and I₂ as a function of the control voltage ΔV_{GS}, with I_{STIG} as a parameter (I_{STIG}=50 mA, 100 mA and 150 mA), and I₁ and I₂ normalized to I_{STIG} The graph in FIG. 2 is simulated with a Microsim PSPice software package for values of V_{GS}=5 V, 1 mH inductor coils, and model 2N7000 MOSFET transistors (R_{DS}=5 Ohm@V_{GS}=10 V), and does not take into account the effect of parasitic diodes 13a, 13b, 13c, and 13d. The parasitic diodes cause a voltage drop through the respective coils when they become forward biased, thereby contributing to a current error for differing values of I_{STIG}, as discussed below. The graph shows that the currents I₁ and I₂ are equal to 50% of I_{STIG} when the control voltage ΔV_{GS}=0, such that V_{GS1}=V_{GS2}.

The maximum error for current I₁, when I_{STIG} is varied from 50 mA to 150 Ma and the parasitic diodes are not taken into account, is shown to be 0.7% over the entire range of ΔV_{GS}. This low maximum error value guarantees that the current ratios will be kept constant when I_{STIG} is varied. This is important because stigmation calibration is performed by first determining the ratios I₁/I_{STIG}, I₂/I_{STIG}, I₃/I_{STIG}, I₄/I_{STIG} and then adjusting the value of I_{STIG}.

Current I_{STIG} is supplied to coils L1-L4 to adjust the cross-sectional shape of the electron beam passing through the apertures and magnetic lenses. In particular, these lenses tend to change the electron beam focal point along the x-axis and y-axis by distorting the electron beam's original circular cross-section to an elliptical cross-sectional shape. Experience shows that after setting the initial stigmation balance voltages and stigmation currents, the stigmation currents do not fluctuate beyond 50 mA when they are recalibrated on a daily basis.

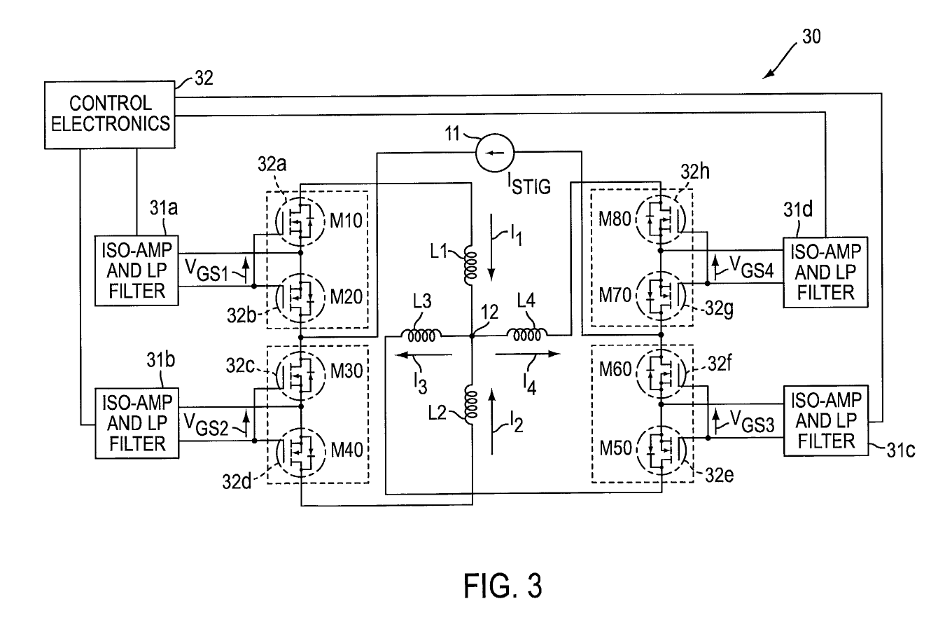

FIG. 3 shows a second embodiment of the present invention with transistor pairs M10, M20 replacing the single transistor M1, shown in FIG. 1. Each transistor pair includes a common source terminal connection and a common gate terminal connection, with the drain terminal of transistor M10 being connected to coil L1 and the drain terminal of transistor M20 being connected to one end of constant current source I_{STIG}. Transistors M10 and M20 are paired to minimize the effect of the parasitic diodes 32a,32b between the drain and source terminals of transistors M10 and M20, respectively. The parasitic diodes cause a voltage drop across a corresponding coil when they becomes forward biased. The voltage drop across the coil gives rise to a current error through a respective coil current when the value of I_{STIG} is varied. As previously described, a small current error is desirable because stigmation calibration is performed by first determining the ratios of I₁/I_{STIG}, I₂/I_{STIG}, I₃/I_{STIG}, I₄/I_{STIG} and then adjusting the value of I_{STIG} Thus, the current ratios must be kept unchanged when varying I_{STIG}.

The effect of the parasitic diodes 32a,32b is minimized by pairing the transistors, as illustrated in FIG. 3, so that one parasitic diode remains reverse biased while the other is forward biased. If transistors M10, M20, M30 and M40 are identical, then their response to positive and negative polarities of I_{STIG} will be symmetrical and the voltage drop across each coil L1, L2, L3, and L4 will be distributed between a pair of corresponding transistors (i.e., M10 and M20 of FIG. 3) instead of only one transistor (i.e., M1 of FIG. 1). The transistor configuration of FIG. 3 effectively eliminates the voltage drop across the respective coil, thus reducing the current error for varied values of I_{STIG}.

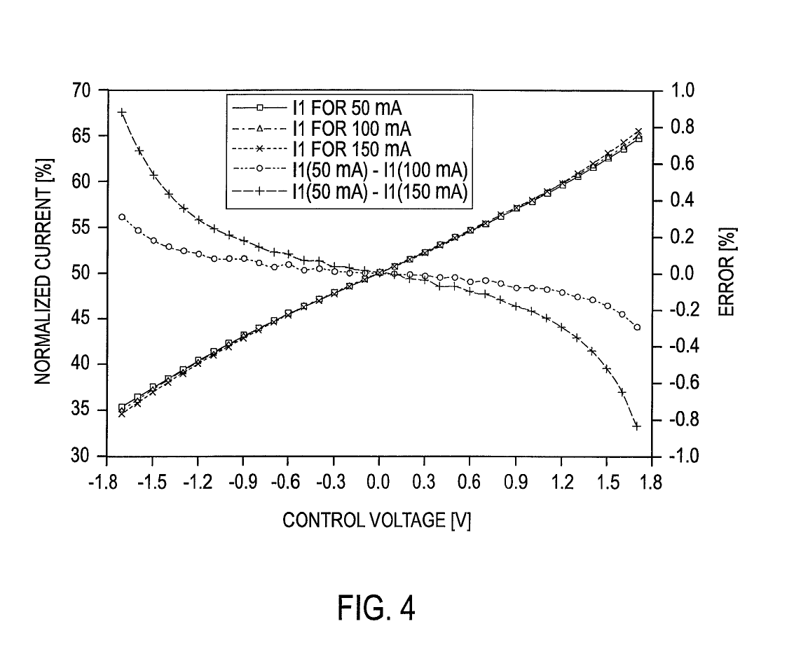

FIG. 4 shows a graph of a simulated DC analysis for circuit 30 of FIG. 3. The graph shows I₁ as a function of the control voltage ΔV_{GS}, with I_{STIG} as a parameter (I_{STIG}=50 mA, 100 mA and 150 mA), and I₁ and I₂ normalized to I_{STIG} The graph in FIG. 4 is simulated with a Microsim PSPice software package using coil values of 9 Ohm resistance. The current range in FIG. 4 is approximately the same as one that can be achieved when using 10 Ohm potentiometers as shown in FIG. 7. Due to the transistor pairing so that one parasitic diode remains reverse biased while the other is forward biased, the results are identical when I_{STIG} is inverted. FIG. 4 also shows a difference between I₁ curves of different values of I_{STIG}. The maximum observed error over the entire range is lower than 1%, whereas the maximum error for I₁ for the 50 mA and 150 mA curves is under 0.5% for the range 40% <I₁/I_{STIG}<60%.

Stigmation adjustment circuit 30 includes isolation amplifiers 31a-31d which provide floating voltage values for V_{GS1}, V_{GS2}, V_{GS3} are V_{GS4} to balance the voltages across and currents through the coils. The isolation amplifiers also include low pass filters at their outputs to reduce the interference of the internal oscillators which operate at relatively high frequencies. The stigmation adjustment circuit 30 also includes control electronics that are simple and can be developed using D/A converters and operational amplifiers, thus a detailed description is omitted.

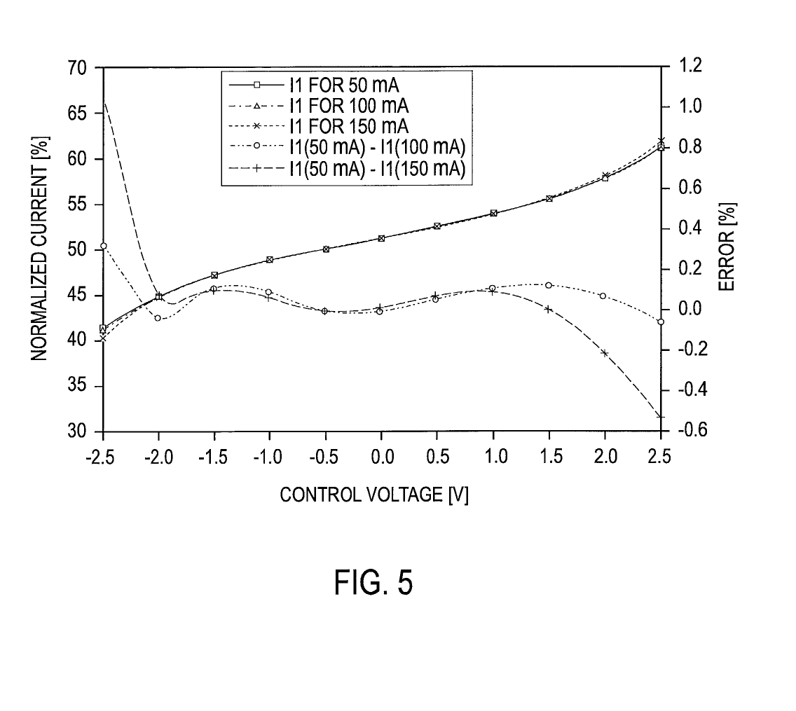

FIG. 5 shows a graph of measured DC analysis for current I₁ vs. the control voltage (V_{GS}) circuit of FIG. 3 at different I_{STIG} current levels (i.e., I_{STIG}=50 mA, 100 mA, and 150 mA), wherein I₁ is normalized to I_{STIG} and includes the observed error between the 50 mA and 150 mA curves. The maximum error between I₁ curves (for I_{STIG} equal to 50 and 150 mA) is under 0.5% for 43% <I_{STIG}<60%, however, for smaller changes of I_{STIG} the error decreases. The I₁ error curve shows, for I_{STIG} equal to 50 and 100 mA, the error is under 0.5% for a wider current range (40% <I₁/I_{STIG}<60%).

Analysis shows that a 100% change of the total stigmation current I_{STIG}, introduces an error lower than 0.5% to the component currents I₁, I₂, I₃, and I₄. This is true for currents ranging between 40 and 60% of I_{STIG}. When a 200% change to I_{STIG} is introduced, the same kind of error can be maintained for a reduced range of currents between 43% and 60% of I_{STIG} For larger currents, such as 35% to 65 % of I_{STIG}, the error increase is significant.

Generally, calibration within the above described ranges can be achieved by adjusting the current ratios I₁/I_{STIG}, I₂/I_{STIG}, I₃/I_{STIG}, I₄/I_{STIG} via control voltages (ΔV_{GS}) and by determining the value of I_{STIG}. If it is desired to increase the current ranges, while keeping errors low, additional steps must be performed, such as setting of control voltages through look-up tables, etc.

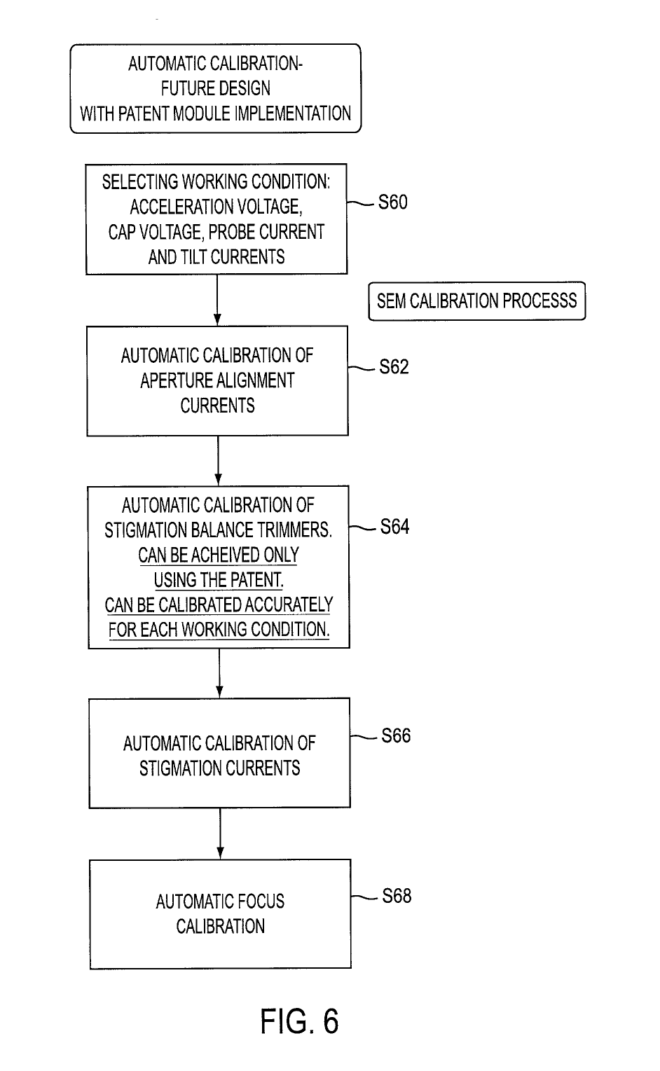

FIG. 6 illustrates a method for calibrating stigmation magnetic lenses according to the present invention. In step S60, the working conditions of a scanning electron microscope are selected. For example, an acceleration voltage, cap voltage, probe current and tilt currents are selected for a desired specimen under test. Next, in step S62, the aperture alignment currents are automatically calibrated. In step S64, the stigmation balance trimmers are automatically calibrated for each working condition. Due to the nature of the remotely controlled, automatic calibration, it is possible to perform calibration of the stigmation balance trimmers each time a working condition is changed. In steps S66 and S68, automatic calibration of stigmation currents and automatic focus calibration are performed, respectively.

While the preferred forms of the present invention have been described, it is to be understood that modifications will be apparent to those skilled in the art without departing from the spirit of the invention. The scope of the invention, therefore, is to be determined solely by the following claims.

What is claimed is:

1. A calibration device which provides resistance-based adjustment using ohmic characteristics of a transistor, wherein the calibration device comprises:
a constant current source;
a plurality of coils which are commonly connected at one end; and
a plurality of transistors, each of said transistors being connected to a corresponding second end of said coils and to said constant current source.

2. The calibration device according to claim 1, wherein said transistors are Metal-Oxide-Semiconductor Field Effect transistors (MOSFETs).

3. The calibration device according to claim 2, wherein said MOSFETs provide low-resistance adjustment.

4. The calibration device according to claim 1, further comprising control electronics connected to said transistors for automatic calibration.

5. The calibration device according to claim 4, wherein said control electronics provide remote control adjustment.

6. The calibration device according to claim 1, wherein said coils form a quadrapole lens.

7. The calibration device according to claim 1, wherein said coils form stigmation magnetic lenses.

8. A calibration device for a scanning electron microscope which provides resistance-based adjustment using ohmic characteristics of a transistor to re-shape a non-circular electron beam into a circular electron beam prior to the electron beam impinging a specimen to be analyzed, wherein the calibration device comprises:
a constant current source;
a plurality of coils which are commonly connected at one end;
a plurality of transistor pairs, each of said transistor pairs being connected to a corresponding second end of said coils and to said constant current source;
a plurality of isolation amplifiers connected to said transistor pairs; and
control electronics connected to said isolation amplifiers to provide automatic calibration.

9. The calibration device according to claim 8, wherein said transistors are Metal-Oxide-Semiconductor Field Effect transistors (MOSFETs).

10. The calibration device according to claim 9, wherein said MOSFETs provide low-resistance adjustment.

11. The calibration device according to claim 8, wherein said control electronics provide remote control adjustment.

12. The calibration device according to claim 8, wherein said coils form a quadrapole lens.

13. The calibration device according to claim 8, wherein said coils form stigmation magnetic lenses.

14. A scanning electron microscope comprising:
an electron gun which produces an electron beam; and
an electron column, comprising:
at least one magnetic lens, wherein one of said at least one magnetic lens provides an automatic calibration of a stigmator;
at least one electrostatic lens; and
a set of coils for deflecting the electron beam.

15. The scanning electron microscope of claim 14, wherein the automatic calibration stigmator provides resistance-based adjustment using ohmic characteristics of a transistor and comprises:
a constant current source;
a plurality of coils which are commonly connected at one end; and
a plurality of transistors, each of said transistors being connected to a corresponding second end of said coils and to said constant current source.

16. The scanning electron microscope of claim 15 wherein the automatic calibration stigmator automatically corrects for aberrations in the electron beam.

17. A method of adjusting current values in a scanning electron microscope using ohmic characteristics of a transistor, said scanning electron microscope comprising a constant current source, a plurality of coils which are commonly connected at one end, and a plurality of transistors, each of said transistors being connected to a corresponding second end of said coils and to said constant current source, comprising the steps of:
(a) performing automatic calibration of aperture alignment currents for selected working conditions; and
(b) performing automatic calibration of stigmation balance trimmers for the selected working conditions.

18. The calibration method according to claim 17, further comprising the steps of:
(c) performing automatic calibration of stigmation currents for the selected working conditions; and
(d) performing automatic focus calibration for the selected working conditions.

19. The calibration method according to claim 17, wherein selecting the working conditions comprise:
(a1) selecting an acceleration voltage;
(a2) selecting a cap voltage;
(a3) selecting a probe current; and
(a4) selecting a tilt current.

20. A method of adjusting quadrupole stigmation magnetic lenses of a scanning electron microscope using ohmic characteristics of a transistor in order to provide flexibility in working with a variety of aperture and acceleration voltages and to enable modification of a cross-sectional shape of an electron beam, said scanning electron microscope comprising a constant current source, a plurality of coils which are commonly connected at one end, and a plurality of transistors, each of said transistors being connected to a corresponding second end of said coils and to said constant current source, comprising the steps of:
(a) supplying a constant current through said coils; and
(b) adjusting a voltage applied across selected ones of said transistors to vary the ohmic characteristics of said selected transistors, wherein the applied voltage has a floating ground potential.
